(19) United States
(12) Patent Application Publication
(10) Pub. No.: US 2003/0106488 A1
(43) Pub. Date: Jun. 12, 2003

(54) Manufacturing method for semiconductor quantum particles

(76) Inventors: Wen-Chiang Huang, Auburn, AL (US); Lulu Song, Auburn, AL (US)

Correspondence Address: Wen-Chiang Huang, 2076, S. Evergreen Dr., Auburn, AL, 36830, US

(21) Appl. No.: 10/007,563

(22) Filed: Dec. 10, 2001

(51) Int. Cl. C30B 7/00; C30B 21/02; C30B 28/06; H01L 21/00

(52) U.S. Cl. 117/68

(57) ABSTRACT

A method for producing compound semiconductor quantum particles from at least a metallic element selected from Groups IB, IIA, IIB, IIIA, IVA, and VA of the Periodic Table and at least a non-oxygen reactant element selected from the group consisting of P, As, S, Se, and Te. The method includes the steps of: (a) mixing a first precursor composition containing at least a metallic element with a second precursor composition containing at least a reactant element to form a reacting fluid in which nanometer-size compound semiconductor clusters are precipitated out of a liquid medium; (b) operating an atomizer to a break up the reacting fluid into micron- or nanometer-size fluid droplets with each fluid droplet containing a predetermined, but small number of nanometer-size compound semiconductor clusters dispersed in the liquid medium for the purpose of constraining the growth of the clusters; (c) directing the fluid droplets into a material treatment stage to further separate and/or passivate the clusters to form the desired compound semiconductor quantum particles; and (d) drying and collecting the quantum particles in a solid powder form.

The present invention is a result of a research sponsored by the SBIR Program of U.S. National Science Foundation. The U.S. government has certain rights on this invention.

### FIELD OF THE INVENTION

The present invention relates to a method for producing nanometer-sized semiconductor particles using a solution synthesis approach. More particularly, it relates to a method for producing quantum-sized compound semiconductor particles (diameter smaller than 20 nm or 200 Å) at a high production rate.

### BACKGROUND

Nanometer-sized semiconductor crystals are of technological significance due to their unique physical properties such as size quantization, non-linear optic behaviors, and unusual luminescence. Nanometer-sized semiconductor crystals (or crystallites) or “quantum dots” whose diameter is smaller than the bulk exciton Bohr diameter (up to 20 nm, but normally smaller than 10 nm in diameter) represent a class of materials intermediate between molecular and bulk forms of matter. Quantum confinement of both the electron and hole in all three dimensions leads to an increase in the effective band gap of the semiconductor material with decreasing crystallite size. As a result, both the optical absorption and emission of quantum dots shift to the higher energies (blue shift) as the size of the dots gets smaller. Nanometer-sized semiconductor crystallites that show such a quantum size effect are also referred to as quantum-sized crystals or quantum nano crystals. Among these, most notable are I-VII, II-VI, III-V, III-VI and IV-VI compound semiconductors.

Quantum-sized compound semiconductors have been found to provide an electro-luminescent device capable of emitting light of various visible wavelengths in response to external stimulus. In such an electro-luminescent device, variations in voltage could result in change of color of the light emitted by the device. Since these classes of light emitting materials are inorganic materials, they are capable of withstanding higher temperatures than the conventional organic polymeric materials for light-emitting applications.

Fluorescent labeling of biological systems is a well known analytical tool used in modern biotechnology as well as analytical chemistry. Applications for such fluorescent labeling include technologies such as medical fluorescence microscopy, histology, flow cytometry, fluorescence in-situ hybridization for medical assays and research, DNA sequencing, immuno-assays, binding assays, separation, etc. Quantum-sized semiconductor crystals have been found to provide stable probe materials for biological applications having a wide absorption band. These crystals are capable of exhibiting either a detectable change in absorption or of emitting radiation in a narrow wavelength band, without the presence of the large red emission tails characteristic of dye molecules. This feature makes it possible to permit the simultaneous use of a number of such probe materials, each emitting light of a different narrow wavelength band and/or being capable of scattering or diffracting radiation. These stable probe materials can be used to image the same sample by both light and electron microscopy.

In addition, compound semiconductor materials comprised of metals and Group 16 elements (commonly referred to as Group VIA chalcogens) are important candidate materials for photovoltaic applications (solar cells), since many of these compounds or metal chalcogenides have optical band gap values well within the terrestrial solar spectra. Mixed-metal chalcogenide semiconductors, such as copper-indium-diselenide (CuInSe₂), copper-gallium-diselenide (CuGaSe₂), and copper-indium-gallium-diselenide (CuIn₁₋ₓ.GaₓSe₂), all of which are sometimes generically referred to as Cu(In,Ga)Se₂ are of particular interest for photovoltaic device applications because of their high solar energy to electrical energy conversion efficiencies. Sulphur (S) can also be substituted for selenium, so the compound is sometimes also referred to even more generically as Cu(In,Ga)(Se,S)₂ to comprise all of those possible combinations.

The following patents are believed to represent the state of the art of the manufacturing methods for semiconductor quantum particles:

1. S. Weiss, et al., “Semiconductor nanocrystal probes for biological applications and process for making and using such probes,” U.S. Pat. No. 6,207,392 (Mar. 27, 2001).

2. A. P. Alivisatos, et al., “Process for forming shaped group II-VI semiconductor nanocrystals, and product formed using process,” U.S. Pat. No. 6,225,198 (May 1, 2001).

3. A. P. Alivisatos, et al., “Preparation of III-V semiconductor Nanocrystals,” U.S. Pat. No. 5,505,928 (Apr. 9, 1996).

4. A. P. Alivestos, et al., “Electroluminescent devices formed using semiconductor nanocrystals and an electron transport media and method of making such electroluminiscent devices,” U.S. Pat. No. 5,537,000 (Jul. 16, 1996).

5. S. Weiss, et al., “Organic luminiscent semiconductor nanocrystal probes for biological applications and process for making and using such probes,” U.S. Pat. No. 5,990,479 (Nov. 23, 1999).

6. A. P. Alivestos, et al., “Semiconductor nanocrystals covalently bound to solid inorganic surfaces using self-assembled monolayers,” U.S. Pat. No. 5,751,018 (May 12, 1998).

7. M. G. Bawendi, et al., “Water-soluble fluorescent nanocrystals,” U.S. Pat. No. 6,251,303 (Jun. 26, 2001).

8. M. G. Bawendi, et al., “Highly luminescent color-selective materials and method of making thereof,” U.S. Pat. No. 6,207,229 (Mar. 27, 2001).

9. N. M. Lawandy, “Semiconductor nanocrystal display materials and display apparatus employing same,” U.S. Pat. No. 5,882,779 (Mar. 16, 1999).

10. A. L. Huston, “Glass matrix doped with activated luminiscent nanocrystalline particles,” U.S. Pat. No. 5,585,640 (Dec. 17, 1996).

11. H. F. Gray, et al. “Nanoparticle phosphors manufactured using the bicontinuous cubic phase process,” U.S. Pat. No. 6,090,200 (Jul. 18, 2000).

12. J. Yang, “Formation of nanocrystalline semiconductor particles within a bicontinuous cubic phase,” U.S. Pat. No. 6,106,609 (Aug. 22, 2000).

13. S. L. Castro, et al., “Functionalized nanocrystals and their use in detection systems,” U.S. Pat. No. 6,114,038 (Sep. 5, 2000).

14. E. Barbera-Guillem, “Lipophilic, functionalized nanocrystals and their use for fluorescence labeling of membranes,” U.S. Pat. No. 6,194,213 (Feb. 27, 2001).

15. D. Gallagher, et al., “Method of manufacturing encapsulated doped particles,” U.S. Pat. No. 5,525,377 (Jun. 11, 1996).

16. C. Lawton, “Biomolecular synthesis of quantum dot composites,” U.S. Pat. No. 5,985,353 (Nov. 16, 1999).

17. O. Siiman, et al., “Semiconductor nanoparticles for analysis of blood cell populations and method of making same,” U.S. Pat. No. 6,235,540 (May 22, 2001).

18. J. C. Linehan, et al. “Process of forming compounds using reverse micelle for reverse microemulsion systems,” U.S. Pat. No. 5,770,172 (Jun. 23, 1998).

19. C. B. Murray, et al. “Method for producing nanoparticles of transition metals,” U.S. Pat. No. 6,262,129 (Jul. 17, 2001).

20. A. N. Goldstein, “Narrow size distribution silicon and germanium nanocrystals,” U.S. Pat. No. 6,268,041 (Jul. 31, 2001).

21. E. Barbera-Guillem, “Continuous flow process for production of semiconductor nanocrystals,” U.S. Pat. No. 6,179,912 (Jan. 30, 2001).

22. D. L. Schulz, et al., “Solution synthesis of mixed-metal chalcogenide nanoparticles and spray deposition of precursor films,” U.S. Pat. No. 6,126,740 (Oct. 3, 2000).

23. P. J. Dobson, et al., “Method of producing metal quantum dot,” U.S. Pat. No. 5,965,212 (Oct. 12, 1999).

24. R. L. Wells, et al., “Method of synthesizing III-V semiconductor nanocrystals,” U.S. Pat. No. 5,474,591 (Dec. 12, 1995).

Bawendi and co-workers have described a method of preparing mono-disperse semiconductor nano crystallites by pyrolysis of organometallic reagents injected into a hot coordinating solvent [Ref.8]. This permits temporally discrete nucleation and results in the controlled growth of macroscopic quantities of nanocrystallites. Size selective precipitation of the crystallites from the growth solution provides crystallites with narrow size distributions. The narrow size distribution of the quantum dots allows the possibility of light emission in very narrow spectral widths. Although semiconductor nanocrystallites prepared as described by Bawendi and co-workers exhibit near monodispersity, and hence, high color selectivity, the luminescence properties of the crystallites are poor. Such crystallites exhibit low photoluminescent yield, i.e. the light emitted upon irradiation is of low intensity. This is due to energy levels at the surface of the crystallite which lie within the energetically forbidden gap of the bulk interior. These surface energy states act as traps for electrons and holes which degrade the luminescence properties of the material.

Since mid-1980's, various synthetic approaches have been developed in preparing nano-sized II-VI (Zn and Cd chalcogenides) and IV-VI (Pb chalcogenides) semiconductors. Much of this effort has been aimed at achieving a very narrow particle size distribution. The basic idea is to use the spatial or chemical confinement provided by matrices or organic capping molecules to terminate the growth of nanocrystallites at any desired stage. In most cases, lack of a microscopically uniform environment in the substrates might be the cause for relatively wide size distribution. Both organic and inorganic matrices, such as mono-layers, polymers, inverse micelles, and zeolites have been used to control the particle size. Recently, other researchers have obtained mono-dispersed CdSe nano crystallites based on the pyrolysis of organometallic reagents. This approach makes use of the concept of Ostwald ripening for size selective precipitation of nano crystallites. So far, many efforts have been made to synthesize quantum-sized II-VI semiconductors especially on the CdSₓ.Se₁₋ₓ systems, while much fewer efforts on IV-VI (PbX, X═S, Se, Te) compounds have been reported. The IV-VI group of compound semiconductors exhibits smaller band gaps, greater quantum-size effect and larger optical non-linearity compared to II-VI materials.

Conventional wet chemistry synthesis conducted without matrix assistance tends to result in the production of micron size particles. Various host matrices, such as glass, zeolites, sol-gels, and micelles, have been used to synthesize nano particles. However, a number of problems have been found to be associated with these methods. For instance, the particles synthesized in glasses and sol-gels exhibit large polydispersity, since they are not ordered structures. Another disadvantage with these methods is the inability to easily isolate the nano particles from the matrix material. In the case of micelles, even though it is possible to isolate the particles, the low precursor concentrations required will make mass production of nano particles expensive or impractical.

Compound semiconductor nano crystals, such as Group II-VI ones, may be formed by dissolving a Group II precursor and a Group VI precursor in a solvent and then applying heat to the resulting solution. For example, Group II-VI semiconductor nano crystals may be formed by dissolving a dialkyl of the Group II metal and a Group VI powder in a trialkyl phosphine solvent at ambient temperature, and then injecting the mixture into a heated (340°-360° C.) bath of tri-octyl phosphine oxide (TOPO). While this process is capable of producing Group II-VI semiconductor nano crystals, the results can be somewhat erratic in terms of average particle size and size distribution. This problem of not being reproducible is likely due to the impurities in the technical grade (90% pure) TOPO that adversely influence the reaction. However, substitution of pure TOPO for the technical grade TOPO has also been unsatisfactory, particularly when control of the shape of the particle growth is also desired, clearly because the pure TOPO binds too weakly to the growing crystallites and only weakly associates with the Group II metal to act as a growth retardant, resulting in the growth of spheres rather than any other desired shapes. It seems that the presence of impurities in the technical grade TOPO results in the erratic success of Group II-VI semiconductor nanocrystal growth in technical grade TOPO.

Alivisatos et al. [Ref.3] describes a process for forming Group Ill-V semiconductor nano crystals wherein size control is achieved through use of a crystallite growth terminator which controls the size of the growing crystals. Crystallite growth terminators are said to include a nitrogen-containing or a phosphorus-containing polar organic solvent having an unshared pair of electrons. The patent further states that this growth terminator can complex with the metal and bind to it, thereby presenting a surface which will prevent further crystal growth.

Schulz, et al. [Ref.22] discloses a solution synthesis method for producing mixed-metal chalcogenide nano particles. Wells, et al. [Ref.24] describes a method of synthesizing III-V semiconductor nano crystals in solution at a low temperature. Barbera-Guillem, et al. teaches a five-step, continuous flow process for production of semiconductor nano crystals.

All of these techniques have one or more of the following problems or shortcomings:

(1) Most of these prior-art techniques suffer from a severe drawback: extremely low production rates. It is not unusual to find a production rate of several grams a day. These low production rates, resulting in high product costs, have severely limited the utility value of nano crystals. There is, therefore, a clear need for a faster, more cost-effective method for preparing nanometer-sized semiconductor materials.

(2) Most of the prior-art techniques tend to produce a compound nano crystal product which is constituted of a broad particle size distribution.

(3) Most of the prior-art processes require heavy and/or expensive equipment, resulting in high production costs.

Accordingly, one object of the present invention is to provide an improved method for producing quantum-size semiconductor particles.

Another object of the present invention is to provide a method that is capable of producing a wide range of quantum-size semiconductor particles at a high production rate.

A further object of the present invention is to provide a method for producing semiconductor quantum particles that are surface-passivated.

### SUMMARY OF THE INVENTION

The subject invention provides a method for producing compound semiconductor quantum particles from at least a metallic element preferably selected from Groups IIA, IIB, IIIA, IVA, and VA of the Periodic Table and at least a non-oxygen reactant element selected from the group consisting of P, As, S, Se, and Te. The method includes the following steps:

(a) mixing a first precursor composition (including at least a metallic element) with a second precursor composition (including at least a reactant element) to form a reacting fluid. The reaction between the two precursors results in the formation of a compound semiconductor, which is precipitated out of a liquid medium in the form of nanometer-sized clusters;

(b) operating an atomizer means to a break up this reacting fluid into micron- or nanometer-size fluid droplets, with each fluid droplet containing a predetermined, but small number of nanometer-size compound semiconductor clusters dispersed in the liquid medium for the purpose of constraining the further growth of the precipitated (nucleated) clusters;

(c) directing these fluid droplets into a material treatment means to further separate and/or passivate said clusters to form the desired compound semiconductor quantum particles; and

(d) drying and collecting these quantum particles.

The presently invented process is applicable to essentially all metallic materials, including pure metals and metal alloys. However, for quantum dot applications of compound semiconductor materials, the metal elements in Groups IIA, IIB, IIIA, IVA, and VA of the Periodic Table are preferred substances for use in the practice of the present invention. These elements include Mg, Ca, Sr, Ba, Zn, Cd, Hg, Al, Ga, In, Tl, Ge, Sn, Pb, Sb, and Bi. The reactant elements, P, As, S, Se, or Te, alone or in combination, are directed to react with the metal droplets or clusters to form the desired compound semiconductors, which include particles of phosphide, arsenide, sulfide, selenide, and/or telluride.

Advantages of the present invention may be summarized as follows:

1. A wide variety of quantum-sized compound semiconductor particles can be readily produced. The starting metal materials can be selected from any element in the Groups IIA, IIB, IIIA, IVA, and VA of the Periodic Table. The corresponding partner gas reactants may be selected from the group consisting of P, As, S, Se, Te and combinations thereof. No known prior-art technique is so versatile in terms of readily producing so many different types of quantum semiconductor powders.

2. The apparatus needed to carry out the invented process is simple and easy to operate. It does not require the utilization of heavy and expensive equipment. Further, the feeding of metallic wire in a twin-wire arc machine is a continuous process. Hence, the over-all product costs are very low.

### BRIEF DESCRIPTION OF THE DRAWINGS

FIG. 1 A flowchart showing the essential steps of a method for producing quantum-sized compound semiconductor in accordance with a preferred embodiment of the present invention.

### DETAILED DESCRIPTION OF PREFERRED EMBODIMENTS

As used herein, the term “metal” refers to an element of Groups 2 through 13, inclusive, plus selected elements in Groups 14 and 15 of the periodic table. Thus, the term “metal” broadly refers to the following elements:

| | |
|---|---|
| Group 2 or IIA: | beryllium (Be), magnesium (Mg), calcium (Ca), |
| | strontium (Sr), barium (Ba), and radium (Ra). |
| Groups 3-12: | transition metals (Groups IIIB, IVB, VB, VIB, |
| | VIIB, VIII, IB, and IIB), including scandium (Sc), |
| | yttrium (Y), titanium (Ti), zirconium (Zr), |
| | hafnium (Hf), vanadium (V), niobium (Nb), |
| | tantalum (Ta), chromium (Cr), molybdenum (Mo), |
| | tungsten (W), manganese (Mn), technetium (Tc), |
| | rhenium (Re), iron (Fe), ruthenium (Ru), osmium |
| | (Os). cobalt (Co), rhodium (Rh), iridium (Ir), |
| | nickel (Ni), palladium (Pd), platinum (Pt), |
| | copper (Cu), silver (Ag), gold (Au), zinc (Zn), |
| | cadmium (Cd), and mercury (Hg). |
| Group 13 or IILA: | boron (B), aluminum (Al), gallium (Ga), indium |
| Lanthanides: | (In), and thallium (TI). lanthanum (La), cerium |
| | (Ce), praseodymium (Pr), neodymium (Nd), |
| | promethium (Pm), samarium (Sm), europium (Eu), |
| | gadolinium (Gd), terbium (Tb), dysprosium (Dy), |
| | holmium (Ho), erbium (Er), thulium (Tm), |
| | ytterbium (Yb), and lutetium (Lu). |
| Group 14 or IVA: | germanium (Ge), tin (Sn), and lead (Pb). |
| Group 15 or VA: | antimony (Sn) and bismuth (Bi). |

However, in a preferred embodiment, the metal is an element of Groups IB (Cu, Ag, and Au), IIB (Zn, Cd, and Hg), IIIA (Al, Ga, In, and Tl), IVA (Ge, Sn, and Pb), and VA (Sb and Bi) for luminescence applications. In another preferred embodiment, the metal is copper, indium, gallium, or cadmium for photovoltaic device applications.

As used herein, the “reactant element” is an element selected from Group 15 (or Group VA, including phosphorus (P) and arsenic (As)) or Group 16 (or Group VIA, including sulfur (S), selenium (Se), and tellurium (Te)). The term “chalcogen” normally refers to an element of Group 16 of the periodic table (including S, Se, and Te). The term “chalcogenide” normally refers to a binary or multinary compound containing at least one chalcogen and at least one more electropositive element or radical (e.g., from one of the metal elements defined earlier). Preferably, the chalcogen is sulfur, selenium, or tellurium, and the “metal chalcogenide” is preferably a metal sulfide, a metal selenide, a metal telluride, or some mixture thereof. For the purposes of specification and claims herein, however, the term “chalcogen” refers to an element selected from the group consisting of P, As, S, Se, and Te) and the term “metal chalcogenide” includes a metal phosphide, a metal arsenide, a metal sulfide, a metal selenide, a metal telluride, or some mixture thereof, unless otherwise indicated.

The “metal salt” used in the methods of the present invention may be any compound which contains a metal, and whose sodium salt (e.g., NaX) is soluble in the organic solvent used to precipitate the metal chalcogenide. When used in the context of a metal salt, the term “salt” refers to halogenides, sulfates, nitrates, phosphates, complex salts, alcoholates, phenolates, carbonates, carboxylates, metallo-organic compounds, and the like. Preferably, the salt is a halogenide (e.g., NaI) or a metallo-organic compound.

This invention provides a method of producing compound semiconductor nano particles, including metal phosphide, metal arsenide, and metal chalcogenide nano particles by using a solution synthesis process. The metal phosphide, arsenide, and chalcogenide nano particles are preferably passivated with a capping agent or protective coating. The development of nano crystals in a solution synthesis process typically involves three distinct phases: nucleation (initial formation of particle nuclei, which are nanometer-scaled clusters of atoms, ions, and/or molecules), crystal growth (addition of metal cation and anion to the growing faces of crystal lattices of particle nuclei rather than being consumed in the formation of new particle nuclei), and termination of crystal growth. The method according to the present invention is directed to precisely manipulating parameters for controlling the crystallization processes involved in production of semiconductor nano crystals.

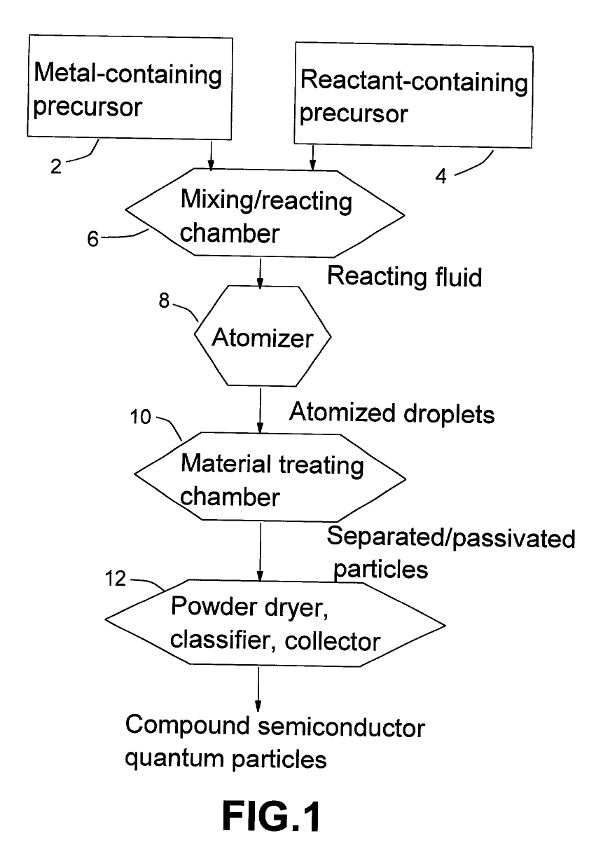

In one embodiment of the present invention, referring to FIG. 1, the method includes:

(a) providing a metal-containing precursor 2 and a reactant-containing precursor 4 and allowing these two precursors to mix and react in a mixing/reacting chamber 6 to form a reacting fluid. The reaction product, a compound semiconductor in the form of nanometer-sized clusters or “nuclei”, will precipitate out of a fluid medium. For instance, the first step may involve reacting a metal salt with a chalcogenide salt (or phosphide or arsenide salt) in an organic solvent to precipitate nano-size clusters of a compound semiconductor (e.g., a metal chalcogenide, phosphide, or arsenide) out of a solution;

(b) operating an atomizer means 8 to produce ultra-fine liquid droplets (each droplet containing a small number of nano-size clusters) to constrain or terminate the growth of these nano clusters;

(c) directing these liquid droplets into a material treatment means 10 (e.g., a chamber containing a fluid medium that contains a volatile capping agent to cap, passivate or protect the nano clusters) to produce stabilized (separated and/or passivated) nano particles; and

(d) operating a powder dryer, classifier, or collector 12 to dry and collect these nano particles in a solid powder form.

Atomizers are well-known in the art. Examples of an atomizer that can be used in the practice of the subject invention are given in U.S. Pat. No. 5,059,357 (Oct. 22, 1991 to Wolf, et al.) and U.S. Pat. No. 5,723,184 (Mar. 3, 1998 to Yamamoto).

As indicated earlier, for the purpose of providing a detailed description and an enabling embodiment, but not for the purpose of limitation, this description hereinafter uses the term “metal chalcogenides” to include metal pnictides (phosphides and arsenides) and conventional metal chalcogenides (sulfides, selenides, and tellurides). Unless the text indicates otherwise, the term “metal chalcogenides” also includes “mixed-metal chalcogenides,” implying more than one metal element is included in the compound. The present invention can be practiced using any suitable combination of metals and chalcogens, including both binary and multinary systems, and including single- or mixed-metals and/or single- or mixed-chalcogens. Chalcogens in the present description include the conventional chalcogen elements (S, Se, and Te), plus P and As. As will be understood by those of skill in the art, a “single-metal” compound means a compound containing only one type of metal; a “mixed-metal” compound means a compound containing more than one type of metal. Similarly, a “single-chalcogenide” means a compound containing only one type of chalcogen; a “mixed-chalcogenide” means a compound containing more than one type of chalcogen. Thus, for example, the metal chalcogenide compounds of the present invention may be expressed according to the following general formula:

M₁ M₂ . . . Mₙ (P,As,S,Se,Te)

where M₁ M₂ . . . Mₙ is any combination of metals, and (P,As,S,Se,Te) is any combination of P, As, S, Se, and/or Te.

The “chalcogenide salt” used in the methods of the present invention may be any compound which contains a chalcogen (P, As, S, Se, or Te), and which reacts with a metal salt to form a metal chalcogenide. As used herein, “chalcogenide salt” refers to a salt of the chalcogenide anion which is partially soluble in the reaction medium, including, but not limited to, alkali or alkaline-earth metal salts of the corresponding anion. Preferably, the salt contains a metallic element of Group 1. In a particularly preferred embodiment, the salt contains sodium or potassium. The metal salt and the chalcogenide salt are selected in such a manner that the resulting metal chalcogenide is insoluble or slightly soluble in the reaction medium. Thus, any metal salt and any chalcogenide salt which react to produce an insoluble or slightly soluble chalcogenide product are useful reagents in accordance with the methods of the present invention. It should also be understood that the metal salt(s) and the chalcogenide salt(s) used in the methods of this invention may be applied as individual compounds and/or as mixtures comprising two or more compounds.

For purposes of the specification and claims, the term “semiconductor nano crystals” refers to quantum dots (nanometer-size semiconductor crystallites) each comprised of a core comprised of at least one of a Group II-VI semiconductor material (e.g., ZnS, and CdSe), a Group III-V semiconductor material (e.g. GaAs), a III-VI material (e.g. InSe and InTe), a IV-VI material (e.g. SnS, SnSe, and SnTe), or a combination thereof. In an additional embodiment, the semiconductor nano crystal may further comprise a selected dopant (e.g., with a fluorescence property) such as a rare earth metal or a transition metal, as known to those skilled in the art. The doping may be accomplished by using a suitable chemical precursor containing the selected dopant, which is added in the solution process. In a more preferred embodiment, the selected dopant is added in a proper amount for doping during a stage of the process such as in the nucleation step or controlled crystalline growth step so that the selected dopant is incorporated as part of, or embedded within, the crystal lattice of the semiconductor core material.

Preferably, as selected from the aforementioned semiconductor materials, the semiconductor nano crystal comprises a metal cation and an anion (e.g., the anion comprising a chalcogenide when forming a Group II-VI material, or comprising a pnictide (phosphide or arsenide) when forming a Group III-V material) which requires, in a formation process of producing the semiconductor nano crystal, a mixing step, a nucleation step, and an atomization-based controlled growth step. In a more preferred embodiment, the semiconductor nano crystal comprises a metal cation and the anion which requires, in a formation process of producing the semiconductor nano crystal, a mixing step, a nucleation step, an atomization step, a passivation or capping step, and a drying/collecting step. It is possible that more than one temperature is used in the process (e.g., temperature at which nucleation occurs differs with the temperature of the growth termination step or that of passivation).

For purposes of the specification and claims, by the term “particle size” is meant to refer to a size defined by the average of the longest dimension of each particle as can be measured using any conventional technique. Preferably, this is the average “diameter”, as the semiconductor nano crystals produced using the method according to the present invention are generally spherical in shape. However, while preferably and generally spherical in shape, irregularly shaped particles may also be produced using the method. In a preferred embodiment, the semiconductor nano crystals comprise a particle size in the range of approximately 1 nanometer (nm) to approximately 20 nm in diameter.

The term “sol” refers to a two phase material system comprising the coordinating solvent (in combination with a carrier solution, if any, accompanying the starting materials), and the crystalline particles formed as a result of the organometallic reaction between the metal cation and the anion. In subsequent steps, the sol may further comprise semiconductor nano crystals formed as a result of the process.

For the purposes of simplifying the description of the method, material compositions of this invention will focus primarily on several selected compounds only; e.g. Cu(In₁₋ₓGaₓ) Se₂-, CdTe- and CdS-based structures. However, it should be understood that any metal or various combinations of metals including any ratio thereof, may be substituted for the Cu, In, Ga and Cd components and that P, As, S, Te, and Se or various combinations of P, As, S, Te, and Se may be substituted for the P, As, Se, Te and S components described in these methods and compositions, and that such substitutions are considered to be equivalents for purposes of this invention. Also, where several elements can be combined with or substituted for each other, such as In and Ga, or Se, Te and S, in the component to which this invention is related, it is not uncommon in this art to include in a set of parentheses those elements that can be combined or interchanged, such as (In,Ga) or (Se,Te,S). Doping can be used to introduce some dopants into nano-scaled semiconductor particles to change the electronic properties of these particles. Doping is well-known in the art. The descriptions in this specification sometimes use this convenience. Also for convenience, the elements are discussed with their commonly accepted chemical symbols, including copper (Cu), indium (In), gallium (Ga), cadmium (Cd), selenium (Se), sulfur (S), and the like.

The capping agent used in the practice of the present invention to passivate or protect the nucleated nano clusters is preferably a volatile capping agent. This volatile capping agent may be any capping agent (also sometimes referred to as a stabilizing agent) known in the art which is sufficiently volatile such that, instead of decomposing and introducing impurities into the particles, it evolves during the powder formation step. As used herein, the term “volatile” is defined as having a boiling point less than about 200° C. at ambient pressure. The main purpose of the capping agent is to prevent interaction and agglomeration of the nano particles, thereby maintaining a uniform distribution of the colloidal substance (e.g., metal chalcogenide nano particles), the disperse phase, throughout the dispersion medium. Volatile capping agents suitable for use in the present invention are volatile compounds which contain at least one electron pair-donor group or a group which can be converted into such an electron pair-donor group. The electron pair-donor group can be electrically neutral or negative, and usually contains atoms such and O, N or S. Electron pair-donor groups include, without limitation, primary, secondary or tertiary amine groups or amide groups, nitrile groups, isonitrile groups, cyanate groups, isocyanate groups, thiocyanate groups, isothiocyanate groups, azide groups, thio groups, thiolate groups, sulfide groups, sulfinate groups, sulfonate groups, phosphate groups, hydroxyl groups, alcoholate groups, phenolate groups, carbonyl groups and carboxylate groups. Groups that can be converted into an electron pair-donor group include, for example, carboxylic acid, carboxylic acid anhydride, and glycidyl groups. Specific examples of suitable volatile capping agents include, without limitation, ammonia, methyl amine, ethyl amine, actonitrile, ethyl acetate, methanol, ethanol, propanol, butanol, pyridine, ethane thiol, tetrahydrofuran, and diethyl ether. Preferably, the volatile capping agent is methanol, acetonitrile, or pyridine.

The organic solvent (also herein referred to as dispersion medium or dispersing medium) used in the present invention is not critical to the invention, and may be any organic solvent known in the art, including, for example, alcohols, ethers, ether alcohols, esters, aliphatic and cycloaliphatic hydrocarbons, and aromatic hydrocarbons. Specific examples of suitable organic solvents include, without limitation, methanol, ethanol, propanol, butanol, diethyl ether, dibutyl ether, tetrahydrofuran, butoxyethanol, ethyl acetate, pentane, hexane, cyclohexane, and toluene. In a particularly preferred embodiment, the organic solvent is methanol.

In a preferred embodiment and to further illustrate the specifics of the present invention, the method begins by reacting stoichiometric amounts of a metal salt with a chalcogenide salt in an organic solvent at reduced temperature to precipitate a metal chalcogenide. The reaction conditions for the above-discussed metathesis reaction are not critical to the invention. Thus, the reaction between the metal salt and the chalcogenide salt can be conducted under moderate conditions, preferably below room temperature and at atmospheric pressure. The reaction is typically complete within a few seconds to several minutes. Therefore, the reacting chamber is preferably disposed very close to the atomizer or, further preferably, the mixing and reaction are allowed to occur in the chamber of an atomizer. The atomized liquid droplets are directed to enter a tank of liquid, a different or same organic solvent. Because of the large differences in solubility between the resulting metal chalcogenide and the byproduct of the metathesis reaction, the two end products of this reaction can be readily separated from one another using standard separation techniques. Such separation techniques include, for example, sonication of the mixture, followed by centrifugation. The soluble byproduct is then removed, for example, by decanting using a cannula, leaving an isolated slurry of the metal chalcogenide. Volatile capping agent is then added to the isolated metal chalcogenide to produce a non-aqueous mixture. Finally, the mixture is sonicated for a period of time sufficient to facilitate “capping” of the nano particles by the capping agent, thereby forming a stable, non-aqueous colloidal suspension of metal chalcogenide nano particles.

In one embodiment of the present invention, volatile capping agent is included in the reaction mixture during nano particle synthesis. In this embodiment, stoichiometric amounts of the metal and chalcogenide salts are reacted in the presence of the volatile capping agent at a temperature and for a period of time sufficient to produce a nano particle precipitate. The precipitate is separated from the soluble byproduct of the metathesis reaction, then mixed with additional volatile capping agent to produce a non-aqueous mixture. This mixture is then sonicated and centrifuged to produce a concentrated colloidal suspension. The concentrated suspension is then diluted with additional volatile capping agent in an amount sufficient to produce a colloidal suspension suitable for spray drying.

The spray drying step may include a freeze-drying step. Following the solution synthesis of the metal chalcogenite nano particles, the stable colloidal suspension may be spray deposited onto a suitable substrate to form a frozen solution in a low temperature environment. The solvent is then sublimed (directly from the solid state to the vapor state), leaving behind the solid quantum particles.

The passivating material can be selected from the group consisting of an organic monomer, a low molecular weight polymer (oligomer), a metal, a non-metallic element, or a combination thereof. The metallic material is preferably selected from Group IIB, IIIA, IVA, and VA of the Periodic Table. The non-metallic element is preferably selected from the group consisting of P, As, S, Se, Te, or a combination thereof. Another preferred class of passivating materials contains phosphide, sulfide, arsenide, selenide, and telluride that is vaporized to deposit as a thin coating on the compound semiconductor particles. The passivated semiconductor particles not only have a higher tendency to remain isolated (not to agglomerate together), but also have a higher quantum yield when used as a photoluminescent material. The latter phenomenon is presumably due to a dramatic reduction in the surface electronic energy states that would otherwise tend to result in a non-radiative electronic process.

For instance, passivation can be achieved by reaction of the surface atoms of the quantum dots with organic passivating ligands, so as to eliminate the surface energy levels. The CdSe nano crystallites can be capped with organic moieties such as tri-n-octyl phosphine (TOP) and tri-n-octyl phosphine oxide (TOPO). Passivation of quantum dots can also be achieved by using inorganic materials. Particles passivated with an inorganic coating are more robust than organically passivated dots and have greater tolerance to processing conditions necessary for their incorporation into devices. Examples of inorganically passivated quantum dot structures are CdS-capped CdSe, CdSe-capped CdS, ZnS grown on CdS, ZnS on CdSe, CdSe on ZnS, and ZnSe on CdSe.

The following examples describe in detail the formation of selected compound semiconductor quantum particles in accordance with preferred embodiments of the present invention:

### EXAMPLE 1

In order to prepare cadmium telluride nano particles, a nearly stoichiometric ratio of Cd(CH₃)₂ (dimethylcadmium) in (n-C₈H₁₇)₃ P (tri-n-octylphosphine or “TOP”) and (n-C₈H₇)₃ PTe (tri-n-octylphosphinetelluride or “TOPTe”) in TOP were mixed together in a controlled-atmosphere glove box to form a reacting solution that begins to undergo precipitation of CdTe nuclei (nucleation of nano clusters) in a liquid TOP solution. This room-temperature mixture was atomized to produce micron- and nano-size droplets containing nano clusters of CdTe dispersed in TOP. This stream of droplets is directed to enter liquified (n-C₈H₁₇)₃ PO (tri-n-octylphosphine oxide or “TOPO”) solvent maintained at the desired reaction temperature from 54° C. to about 125° C. under N₂ to generate TOPO-capped CdTe particles. After a nominal reaction period of from about one minute to about 60 minutes, in inverse relationship to the reaction temperature, TOPO-capped cadmium telluride nano particles were precipitated and washed with methanol, centrifuged, and the TOPO- and TOP-containing methanol solution was decanted. The nano particles then were isolated from insoluble by-products by preferential dissolution in butanol, centrifugation, and separation via cannula.

### EXAMPLE 2

CdS nano particle were prepared by reacting CdI₂ in methanol with Na₂S in methanol at reduced temperature under inert atmosphere as follows:

CdI₂+Na₂S(in MeOH)→nano-CdS+2NaI (soluble in MeOH)

The by-product of the reaction (i.e., NaI) is soluble in the methanol solvent while the product nano particles of CdS are not. During the chemical reaction, NaI salt is removed from the product mixture with the remaining CdS nano particles forming a stable methanolic colloid. The methanol colloid, diluted with additional amount of MeOH, was then atomized into nano droplets with MeOH being vaporized immediately upon atomization.

### EXAMPLE 3

A solution is prepared by dissolving a 0.002 mole of cadmium acetate in 200 ml of ethanol at room temperature, which is followed by adding 0.002 mole of 3-aminopropyltriethoxysilane. Then, 0.005 mole of H₂S are added to the mixture and stirred at room temperature for 10 minutes. The solution is atomized to produce micron- and/or nano-size droplets that contain nano clusters of CdS. The droplets are directed to enter a tank of water. The clusters are filtered and dried.

### EXAMPLE 4

A solution is prepared by dissolving a 0.1 mole of zinc acetate in 260 ml of ethanol at 80° C., which is followed by adding 2 mole of 3-aminopropyltriethoxysilane. Then, 0.1 mole of H₂S are added to the mixture and stirred for 10 minutes. The solution is atomized to produce micron- and/or nano-size droplets that contain nano clusters of ZnS. The droplets are directed to enter a tank of water, which serves as a flocculent to cause the clusters to precipitate out of solution without permanent agglomeration. The clusters are filtered and dried.

### EXAMPLE 5

Samples of III-V compound semiconductor nano crystals were prepared through the following route: First, (NaK)₃E (E=P, As) was synthesized in situ under an argon atmosphere by combining sodium/potassium alloy with excess arsenic powder or excess white phosphorus in refluxing toluene. To this was added a GaX₃ (when E=As, X=Cl, I; when E=P, X=Cl) solution in diglyme. For the case of GaAs, the mixture was refluxed for 24 hours. The mixture solution was atomized with the stream of liquid droplets being directed to enter a bath of deionized water, which was used to destroy any unreacted arsenide and to dissolve the alkali metal halide products. In the case of the GaP reactions, an ethanol/deionized water solution was used for the same purpose due to solubility of unreacted white phosphorus in ethanol. The resulting suspension was then vacuum filtered in air and the solid collected on the filter paper washed with copious amounts of deionized water followed by washing with acetone and air drying. The dry solid was heated to 350° C. in a sublimator under dynamic vacuum for 2-3 hrs to remove excess Group V element. The resulting light to dark brown materials were GaAs and GaP nano crystals with approximate average particle size range from 6-22 nm as calculated from the X-ray diffraction patterns using the Scherrer equation.

What is claimed:

1. A method for producing compound semiconductor quantum particles from at least a metallic element selected from Groups IB, IIA, IIB, IIIA, IVA, and VA of the Periodic Table and at least a non-oxygen reactant element selected from the group consisting of P, As, S, Se, and Te, said method comprising the steps of:
(a) mixing a first precursor composition comprising said at least a metallic element with a second precursor composition comprising said at least a reactant element to form a reacting fluid comprising nanometer-size compound semiconductor clusters being precipitated out of a liquid medium;
(b) operating an atomizer means to a break up said reacting fluid into micron- or nanometer-size fluid droplets, each said fluid droplet containing a predetermined, but small number of said nanometer-size compound semiconductor clusters dispersed in said liquid medium for the purpose of constraining the growth of said clusters;
(c) directing said fluid droplets into a material treatment means to further separate and/or passivate said clusters to form said compound semiconductor quantum particles; and
(d) drying and collecting said quantum particles.

2. The method as set forth in claim 1, wherein said compound semiconductor quantum particles comprise particles of phosphide, arsenide, sulfide, selenide, and/or telluride.

3. The method as set forth in claim 1, wherein said atomizer means comprises a vortex atomizer and/or ultrasonic atomizer.

4. The method as set forth in claim 1, wherein said material treatment means comprises
(C1) means for directing said fluid droplets into a flocculent liquid;
(C2) means for removing said liquid medium;
(C3) means for vaporizing said liquid medium;
(C4) means for capping said clusters with an organic or inorganic capping agent; and/or
(C5) means for reacting said clusters with a coating agent to form a protective layer on the surface of said clusters.

5. The method as set forth in claim 1, further comprising a step of doping said particles with predetermined dopants.

6. The method of claim 1, wherein the sub-step of passivating said clusters comprises contacting said clusters with a volatile capping agent selected from the group consisting of ammonia, methyl amine, ethyl amine, acetonitrile, ethyl acetate, methanol, ethanol, propanol, butanol, pyridine, ethane thiol, tetrahydrofuran, and diethyl ether.

7. The method of claim 1, wherein said compound semiconductor clusters have an average particle size of from about 1 to about 20 nm.

8. The method of claim 1, wherein said compound semiconductor particles are selected from the group consisting of Cu(In₁₋ₓGaₓ)Se_{y}, where x is 0-1 and y is 1 or 2, CdS, ZnSe, ZnS, ZnTe, PbSe, PbS, and PbTe.

9. The method of claim 1, wherein said first precursor composition is selected from the group consisting of metal halogenides, metal sulfates, metal nitrates, metal phosphates, complex metal salts, metal alcoholates, metal phenolates, metal carbonates, metal carboxylates, and metallo-organic compounds.

10. The method of claim 1, wherein said liquid medium comprises a solvent selected from the group consisting of methanol, ethanol, propanol, butanol, diethyl ether, dibutyl ether, tetrahydrofuran, butoxyethanol, ethyl acetate, pentane, hexane, cyclohexane, and toluene.
